(19) United States
(12) Patent Application Publication
(10) Pub. No.: US 2015/0138103 A1
(43) Pub. Date: May 21, 2015

(54) FLEXIBLE DISPLAY UNIT AND ELECTRONIC APPARATUS

(71) Applicant: Sony Corporation, Tokyo (JP)

(72) Inventor: Shota Nishi, Kanagawa (JP)

(21) Appl. No.: 14/394,653

(22) PCT Filed: May 20, 2013
(86) PCT No.: PCT/JP2013/064556

§ 371 Date: Oct. 15, 2014

(30) Foreign Application Priority Data
Jun. 5, 2012 (JP) 2012-127983

(51) Int. Cl. G06F 1/16; H05K 7/02; G06F 3/041

(52) U.S. Cl. CPC G06F 1/1652; G06F 3/041; G06F 1/1643; H05K 7/02
USPC 345/173; 345/156; 361/749

(57) ABSTRACT

A flexible display panel including driver integrated circuits (ICs) that are directly mounted to the substrate of the panel and that are configured in such a manner that the display panel can be bent at least in one direction to a high degree without breaking the driver ICs or imparting display functions. Compact driver ICs, which have a low dimensional ratio, may be located along one side of the display panel. A side frame, in which includes rigid portions that resist deformation when the panel is bent and deformable portions that facilitate bending are alternately disposed, may be included on a side of the display panel. Driver ICs may be disposed in regions corresponding to the rigid portions. The flexible display panel may be included in an electronic apparatus such as an electronic book.

### TECHNICAL FIELD

The present disclosure relates to a display unit and an electronic apparatus having flexibility or non-rigidness.

### BACKGROUND ART

In recent years, thin display units called electronic papers have been used as books (so-called electronic books). Such thin display units have high flexibility, and a user may physically bend and twist the thin display units.

In a flexible display unit of related art, driver ICs (integrated circuits) are connected to a peripheral portion of a panel through COF (chip-on-film), etc., and this results in a large-sized module. In addition, due to a large number of flexible printed circuits (FPC), the flexibility of the panel is impaired.

On the other hand, directly mounting ICs to a panel without using the FPC (COG: chip-on-glass) reduces a size of a module. For a display unit in which the ICs are directly mounted to the panel, a proposal has been made to arrange the ICs in a line on one side of the panel to allow the panel to be curved, as disclosed in PTL 1, for example.

### CITATION LIST

### Patent Literature

PTL 1: Japanese Unexamined Patent Application Publication No. 2005-338179

### SUMMARY

According to an aspect of an exemplary illustration of one possible embodiment of the present disclosure, there may be provided a flexible display panel that has a display region in which a plurality of display units are disposed on a flexible substrate, and a peripheral region in which a plurality of semiconductor devices are disposed. The plurality of semiconductor devices may be connected to ones of the display units, and may be configured such that the flexible display panel may bend to a minimum bending radius along at least one side thereof.

According to another aspect of the above-described exemplary embodiment, the plurality of semiconductor devices may include first semiconductor devices disposed directly on the flexible substrate along a first side of the display region and second semiconductor devices disposed directly on the flexible substrate along a second side of the display region adjacent to the first side.

According to another aspect of the above-described exemplary embodiment, each of the second semiconductor devices may have a lower dimensional ratio than any of the first semiconductor devices, where a dimensional ratio is a length of a longest dimension in a plane parallel to the substrate divided by a length of a shortest dimension in a plane parallel to the substrate.

According to another aspect of the above-described exemplary embodiment, each of the second semiconductor devices may have a dimensional ratio less than or equal to 2, where a dimensional ratio is a length of a longest dimension in a plane parallel to the substrate divided by a length of a shortest dimension in a plane parallel to the substrate.

According to another aspect of the above-described exemplary embodiment, for each of the second semiconductor devices, its respective length in the first direction may be less than or equal to its respective length in the second direction.

According to another aspect of the above-described exemplary embodiment, each of the second semiconductor devices may be approximately square.

According to another aspect of the above-described exemplary embodiment, each of the second semiconductor devices may be approximately circular.

According to another aspect of the above-described exemplary embodiment, each of the second semiconductor devices may be approximately hexagonal.

According to another aspect of the above-described exemplary embodiment, the plurality of semiconductor devices may include driver integrated circuits configured to drive the plurality of display units.

According to another aspect of the above-described exemplary embodiment, a longest dimension of each of the second semiconductor devices may be shorter than a longest dimension of any of the first semiconductor devices.

According to another aspect of the above-described exemplary embodiment, a dimension of each of the second semiconductor devices in the second direction may be less than or equal to πR/3, where R is the minimum bending radius along the second direction.

According to another aspect of the above-described exemplary embodiment, the plurality of semiconductor devices may include first semiconductor devices disposed along a first side of the display region and second semiconductor devices disposed on a side frame along a second side of the display region adjacent to the first side. The side frame may include rigid sections and deformable cushion sections alternately disposed with the second semiconductor being disposed on the rigid sections of the side frame.

According to an aspect of an exemplary illustration of another possible embodiment of the present disclosure, there may be provided an electronic apparatus comprising the flexible display panel of the above-described exemplary embodiment.

According to another aspect of the above-described exemplary embodiment, the electronic apparatus may further include a flexible laminated body that includes a display section comprising the flexible display panel and a detection section configured to detect an operation of a user.

According to another aspect of the above-described exemplary embodiment, operations of a user detectable by the detection section may include bending of the flexible laminated body and pressing on the flexible laminated body. The detection section may include a location sensor configured to detect a location of a user input device, which may include any one of a stylus and a finger of a user. The electronic apparatus may be configured to change an image displayed by the display section in response to a detected operation of a user, which may include detecting a user bending the laminated body.

It is to be understood that both the foregoing general description and the following detailed description are exemplary, and are intended to provide further explanation of the technology as claimed.

### BRIEF DESCRIPTION OF DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a perspective view showing a configuration of a display unit according to a first embodiment of the present disclosure.

FIG. 2A to FIG. 2C are a view showing a relationship between a length of a driver IC in a bending direction and a minimum bending radius of a panel illustrated in FIG. 1.

FIG. 3 is a perspective view showing a state where the display unit illustrated in FIG. 1 is bent.

(A) of FIG. 4 is a plan view showing an example of a planar shape of the driver IC illustrated in FIG. 1, and (B) of FIG. 4 is a plan view showing a part of (A) of FIG. 4 in an enlarged manner.

(A) of FIG. 5 is a plan view showing another example of the planar shape of the driver IC illustrated in FIG. 1, and (B) of FIG. 5 is a plan view showing a part of (A) of FIG. 5 in an enlarged manner.

FIG. 6 is a perspective view showing a configuration of an existing display unit.

FIG. 7 is a perspective view showing a configuration of a display section according to a second embodiment of the present disclosure.

FIGS. 8A and 8B are each a perspective view showing an electronic apparatus (electronic book) according to an application example of the present disclosure, wherein FIG. 8A illustrates an opened state thereof, and FIG. 8B illustrates a closed state (folded state) thereof.

FIG. 9 is an exploded perspective view showing the electronic book illustrated in FIGS. 8A and 8B.

FIG. 10 is a functional block diagram of the electronic book illustrated in FIGS. 8A and 8B.

FIGS. 11A to 11C are views each schematically showing an example of user operation.

FIGS. 12A and 12B are views schematically showing other examples of the electronic apparatus.

### DESCRIPTION OF EMBODIMENTS

In the following, some embodiments of the present disclosure will be described in detail with reference to the drawings. It is to be noted that the description will be made in the following order.

1. First embodiment (display unit: an example in which driver ICs each having a low dimensional ratio are directly mounted to a panel)
2. Second embodiment (display unit: an example in which a side frame having a caterpillar structure in which rigid sections and deformable cushion sections are alternately arranged is provided at a side of a panel, and driver ICs are mounted along the rigid sections)
3. Application example (electronic apparatus: electronic book)

### First Embodiment

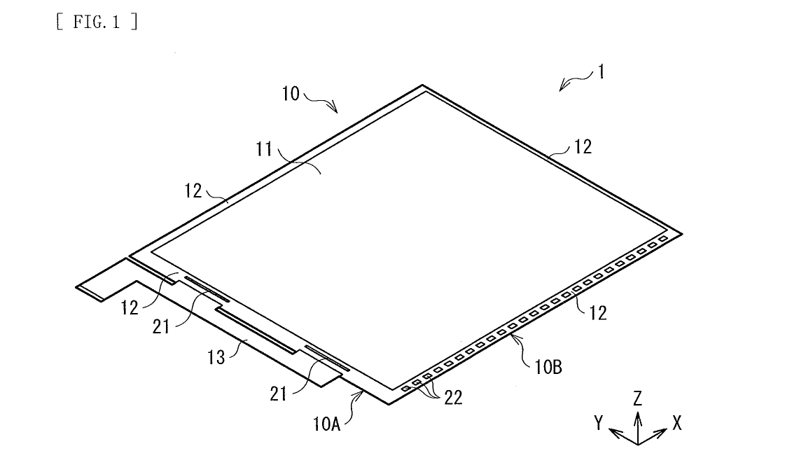

FIG. 1 shows a configuration of a display unit 1 according to a first embodiment of the present disclosure. This display unit 1 may be used as a display section of an electronic book, for example, and is provided with a panel 10 having flexibility. Driver ICs 21, which have an elongated shape (i.e., a high aspect ratio) (hereinafter referred to as “elongated driver ICs 21”), and driver ICs 22, which have a comparatively less elongated shape (i.e., a lower aspect ratio) (hereinafter referred to as “compact driver ICs 22”), are directly mounted at a peripheral portion of the panel 10. The compact driver IC 22 corresponds to a specific but not limitative example of a “semiconductor device” in one embodiment of the present disclosure.

As used herein, a horizontal direction (long side direction) and a vertical direction (short side direction) of a main face (broadest face) of the panel 10 refer to an X-direction and a Y-direction, respectively, and a thickness direction of the panel 10 refers to a Z-direction.

The panel 10 is a display panel that displays an image based on an image signal, and may have a configuration in which an organic EL (electroluminescence) element, a liquid crystal display element, an electrophoretic element, or the like is interposed between resin films of plastic or the like, for example.

The panel 10 may have a rectangular planar shape, and may include a rectangular display region 11 at substantially the center thereof, for example. A peripheral portion 12 disposed outwardly of the display region 11 may be provided with elongated driver ICs 21 mounted along a side thereof. For example, in FIG. 1 two elongated driver ICs 21 are mounted along a short side 10A (Y-direction) of the panel 10, and each is connected with an FPC 13 used to input and output a signal to external connected terminals. The elongated driver IC 21 may be configured of a large-sized IC having a high aspect ratio, for example of 1.5 millimeters wide by 20 millimeters long or more. One advantage of using large-sized ICs with high aspect ratios is that it increases the number of channels collectively processable, and thereby allows for reduction in the number of the elongated driver ICs 21 to be mounted. In addition, since the elongated driver ICs 21 are directly mounted at the peripheral portion 12 of the panel 10, compactification of the display unit 1 is achieved in comparison to the COF (chip-on-film) method of the related art.

The peripheral portion 12 may be also provided with a plurality of the compact driver ICs 22 mounted along another side thereof. For example, in FIG. 1 twenty-six compact driver ICs 22 are mounted along a long side 10B (X-direction) of the panel 10. The compact driver IC 22 has a low dimensional ratio of such an extent that it allows the panel 10 to be bent to a minimum bending radius. With this configuration, the display unit 1 is capable of increasing flexibility and mechanical reliability of the panel 10.

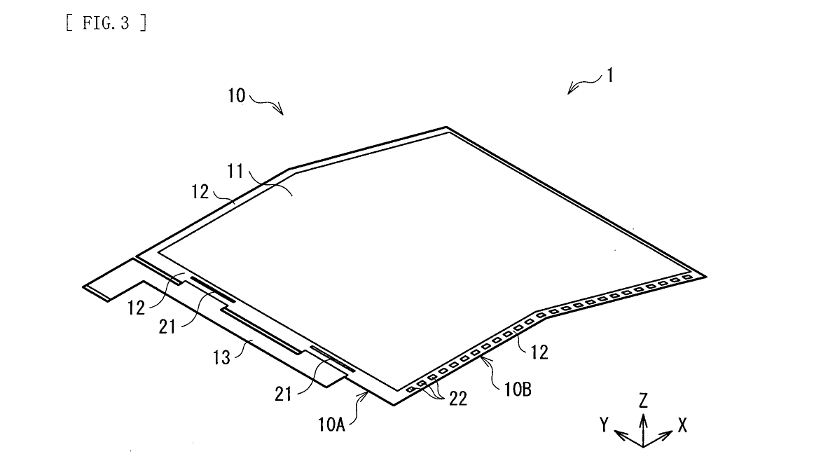

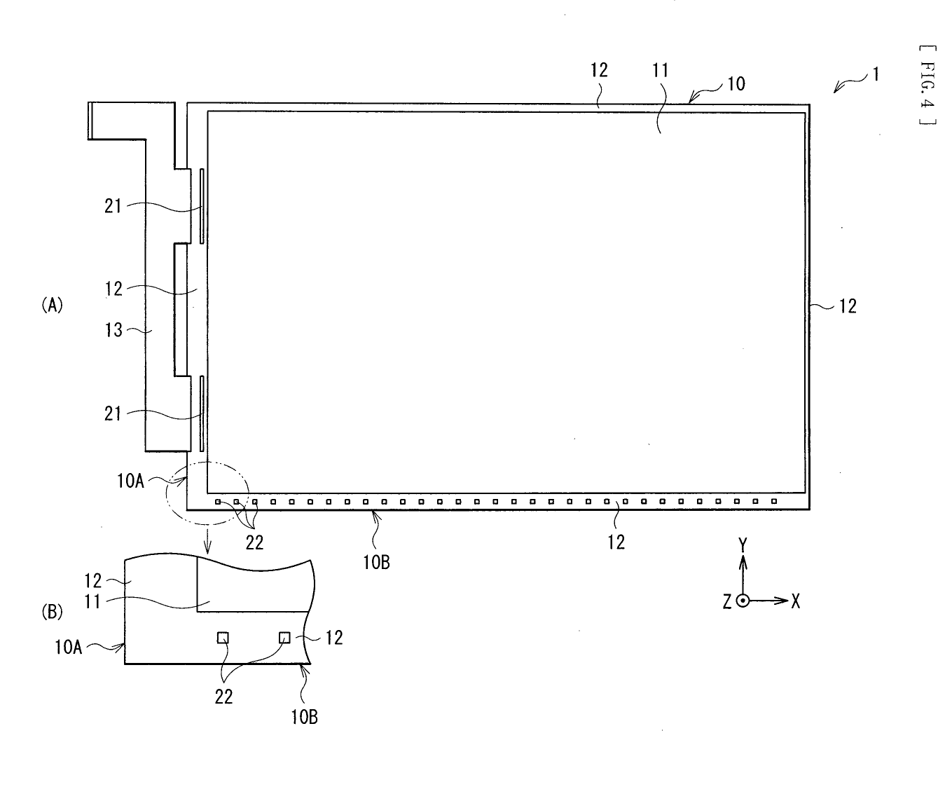

In other words, by using the compact driver ICs 22 as the drivers mounted along a side of the peripheral portion, instead of using existing ICs which are vertically-long and have high aspect ratio, the display panel can be more easily bent without risking damaging the drivers. This is because the compact the driver ICs 22 are more resistant to bending than more elongated ICs, and a risk that the compact driver ICs 22 are broken by bending of the panel 10 is decreased. Consequently, as illustrated in FIG. 3 for example, it is possible to bend the panel 10 while the compact driver ICs 22 are mounted thereto, and to increase the flexibility and the mechanical strength of the panel 10 without impairing the reliability of the compact driver ICs 22 per se.

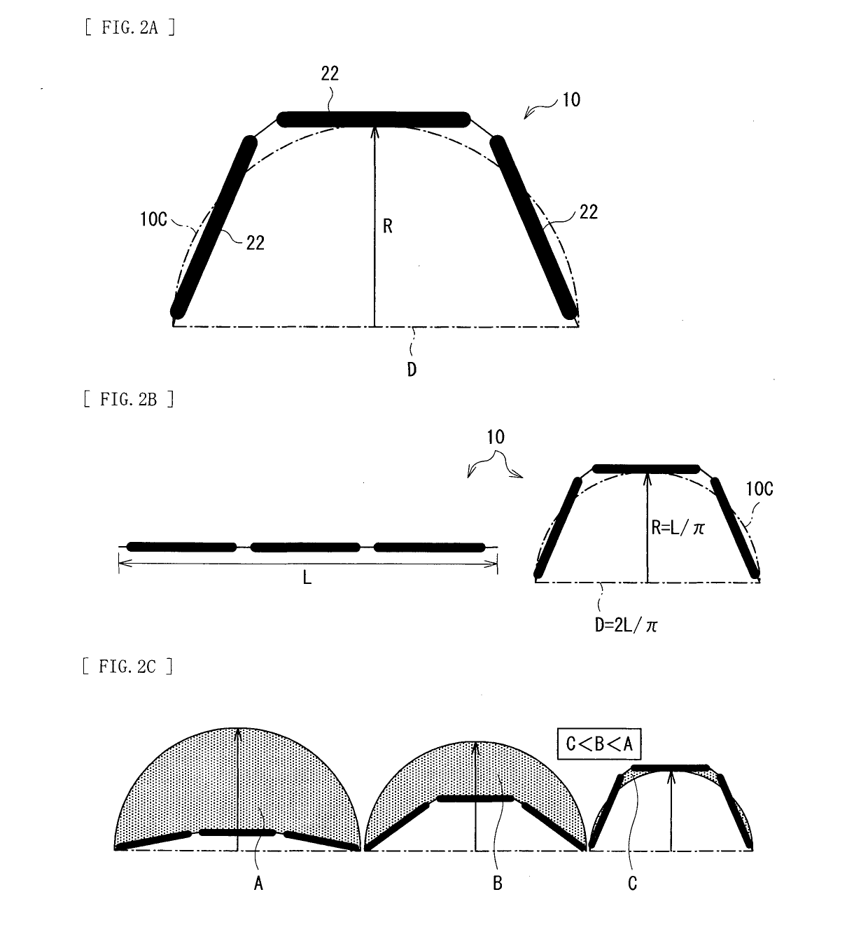

The phrase “bend to a minimum bending radius” is defined as follows. The panel can “bend to a minimum bending radius” if it can be bent at least to the extent that its cross-sectional shape approximates the arc of a semicircle 10C, as illustrated in FIG. 2A, without impairing functionality of the panel. The diameter of the semicircle 10C corresponds to a line connecting both ends of the panel 10. In FIG. 2A, the semicircle 10C is shown by virtual line. As used herein, the term “minimum bending radius” refers to a radius R of the semicircle 10C. One of ordinary skill in the art would understand that the shape of the bent panel might not correspond exactly to the arc of the semicircle 10C with mathematical precision. However, if the shape of the bent panel approximates the arc of the semicircle 10C, then the panel is bent to a “minimum bending radius” as the phrase is used herein. Whether the panel approximates the arc of the semicircle 10C may be determined by any reasonable method of mathematical approximation. For example, the panel approximates the arc of the semicircle 10C if the two ends of the bent panel are the distance D (±10%) from each other, where D=2L/π and L is the length of the panel in a bending direction, as shown in FIG. 2B. As another example, the panel approximates the arc of the semicircle 10C if the distance from the midpoint of the line connecting the two ends of the bent panel to a point on the panel directly above said midpoint (i.e., on a line orthogonally bisecting the line connecting the two ends of the bent panel) is R (±10%), where R=L/π and L is the length of the panel in a bending direction, as shown in FIG. 2B. As another example, the panel approximates the arc of the semicircle 10C if the panel is bent to the extent that the area between the arc of the semicircle 10C and the shape of the bent panel 10 is minimized, as shown in FIG. 2C (i.e., the value Area=|∫f_{semicircle}−∫fₚₐₙₑₗ| is minimized).

As noted above, the definition of “bend to a minimum bending radius” includes the caveat that such bending not impair the functionality of the panel. The panel 10 is provided with the elongated driver ICs 21, the compact driver ICs 22, elements including a TFT and the like, and structural components including an electrode and the like. Therefore, when the panel 10 is forcibly bent, the driver ICs and the elements may break due to a stress, and visually-recognizable degradation and/or image quality deterioration including a non-light emission defect, a luminescent spot defect (a defect that causes a spot that is brighter than other surrounding pixels), and the like may occur, impairing a function as a display unit. Accordingly, “bend to a minimum bending radius” refers to an extent that, when the panel 10 is bent, elements such as the TFT and the driver ICs are not broken, and therefore a function as a display unit is not impaired or visually-recognizable degradation is not caused.

“Dimensional ratio” refers to a ratio of a largest outer size to a smallest outer size of a shape (for example, a ratio of a length to a width of the rectangular compact driver IC 22 if FIG. 1), and is synonymous with an aspect ratio (a ratio of length to width) in one embodiment where the driver IC 22 is rectangular in shape.

Further, specifically, as also illustrated in FIG. 2A to FIG. 2C, it is preferable that a length L₁ of the compact driver IC 22 in a bending direction (here, X-direction) be equal to or lower than πR/3, where R is the minimum bending radius of the panel 10. This is because, in order to approximate a curvature of the bend portion by polygons, it is advantageous to satisfy the above-described condition.

Further, it is preferable that the length L₂ of the compact driver IC 22 in a direction (Y-direction) orthogonal to the bending direction be equal to or smaller than the length L₁ of the long side (X-direction), since this makes it possible to achieve better effect.

Specifically, for example, a size of the compact driver IC 22 may be about 1 mm to about 2 mm both inclusive in width, and may be about 1 mm to about 2 mm both inclusive in length. In addition, for example, the aspect ratio of the compact driver IC 22 may be preferably 3 or less, and more preferably, 2 or less. With this configuration, it is possible to moderate concentration of stress on the center portion of the compact driver IC 22 when the panel 10 is deformed, thereby allowing bending to a greater extent without risk of breaking the driver ICs.

A width of a gap between the compact driver ICs 22 is not specifically limited, as long as a sufficient interval between the compact driver ICs 22 is provided for the size of the compact driver ICs 22.

In addition, as illustrated in (A) and (B) of FIG. 4, the compact driver IC 22 preferably has a square planar shape, and is preferably disposed such that each side of the square is in parallel to the corresponding side of the panel 10. With this configuration, a flexible module resilient even when bent in two directions (two directions that are extension of the length side and the width side of the square) is achieved.

Alternatively, as illustrated in (A) and (B) of FIG. 5, it is also preferable that the compact driver IC 22 has a planar shape of a regular polygon such as a regular hexagon. With this configuration, the directions in which the panel 10 is bendable are increased, and thus a flexible module resilient even when bent multidirectionally (directions that are extension of the respective sides of the regular polygon) is achieved. As used herein, the term “regular polygon” encompasses not only the geometrically-perfect regular polygons, but also polygons having symmetry which may be deemed as near-regular polygons in consideration of factors such as assembly accuracy of the driver ICs. In addition, the planar shape of the compact driver IC 22 may also be a circular shape.

Further, since the driver ICs 22 are directly mounted at the peripheral portion 12 of the panel 10 similarly to the elongated driver ICs 21, it is possible to achieve compactification of the display unit 1 in comparison to the COF (chip-on-film) method of the related art.

In addition, the size in the X-direction of the compact driver IC 22 mounted at the long side 10B (the side in the X-direction) of the panel 10 is shorter than the size in the Y-direction of the elongated driver IC 21 mounted at the short side 10A (the side in the Y-direction) of the panel 10. With this configuration, it is possible to bend the panel 10 of the display unit 1 in the X-direction more easily than in the Y-direction, and to increase the flexibility and the mechanical reliability of the panel 10.

To be more specific, while improvement in the flexibility of the panel 10 is strongly desired, allowing the panel 10 to be bendable and deformable completely freely may lead to breakage of the driver ICs and the elements on the panel 10 by excessive forcible-deformation exceeding an allowable limit, which may impair display performance. Accordingly, restricting the deformation direction of the panel 10 and allowing the panel 10 to be deformable only in a particular direction (for example, in the X-direction, that is, in the long side 10B direction) may be effective in achieving and increasing both the flexibility and the mechanical reliability of the panel 10.

Further, the short side 10A is connected with the FPC 13 together with the elongated driver ICs 21 as described above. Consequently, by disposing the elongated driver ICs 21 and the FPC 13 at the short side 10A which is difficult to be deformed, it is possible to protect the elongated driver ICs 21 and the FPC 13 from breakage due to the deformation of the panel 10.

Except that the compact driver ICs 22 which satisfy the above-described dimensional ratio or dimensional condition are used, the display unit 1 can be manufactured using common manufacturing methods.

In the display unit 1, the compact driver IC 22 has a low dimensional ratio (an aspect ratio in an embodiment of the rectangular compact driver IC 22) of such an extent that allows the panel 10 to be bent to the minimum bending radius of the panel 10. Thus, the compact driver IC 22 is resistant to bending. Consequently, in bending the panel 10, it is possible to bend the panel 10 while the compact driver ICs 22 are mounted thereto as illustrated in FIG. 3, for example.

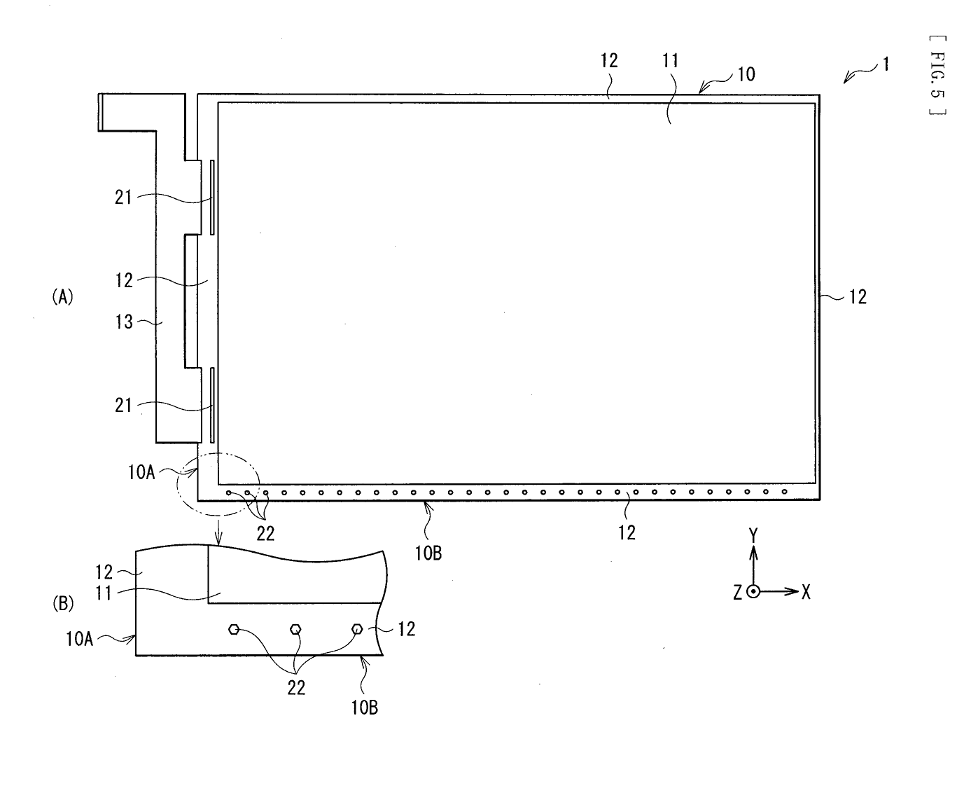

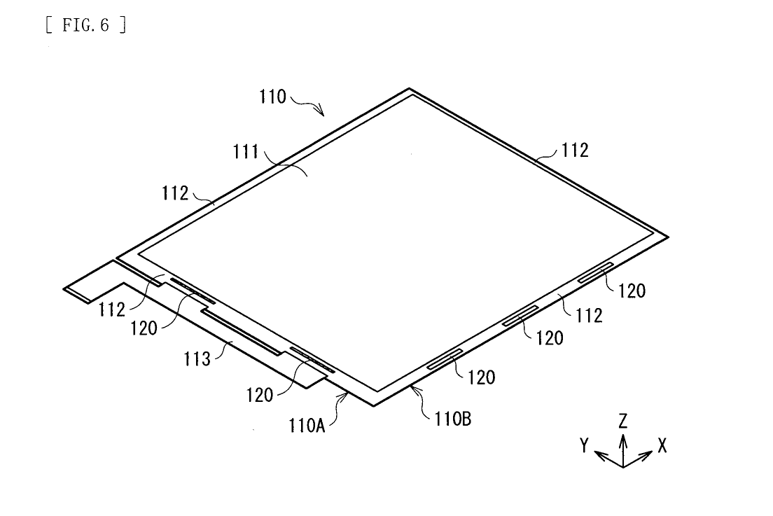

In contrast, in related art, several elongated driver ICs 120 each having a relatively high aspect ratio are mounted to a peripheral portion 112 of a panel 110 along a short side 110A and a long side 110B as illustrated in FIG. 6 for example. Such elongated driver IC 120 having a high aspect ratio may lack flexibility per se, and may easily break when the panel 110 is bent. Therefore, with such an existing IC layout, the flexibility of the panel 110 is impaired. For example, in FIG. 6, since the elongated driver IC 120 is mounted at a center of a long side of the panel 110, it may be difficult to fold the panel 110 at the center of the long side 110B of the panel 110. It is to be noted that, in FIG. 6, elements corresponding to those of FIG. 1 are given like reference numerals in the 100s.

As described, in the present embodiment, the dimensional ratio of the compact driver IC 22 (an aspect ratio in an embodiment of the rectangular compact driver IC 22) has a small value that allows the panel 10 to be bent to the minimum bending radius. Hence, it is possible to improve strength of the compact driver IC 22 against bending, and to increase the flexibility and the mechanical reliability of the panel 10.

In addition, the size in the X-direction of the compact driver IC 22 mounted at the long side 10B (the side in the X-direction) of the panel 10 is shorter than the size in the Y-direction of the elongated driver IC 21 mounted at the short side 10A (the side in the Y-direction) of the panel 10. Hence, it is possible to make the panel 10 easier to bend in the X-direction than in the Y-direction, and to increase the flexibility and the mechanical reliability of the panel 10.

### Second Embodiment

FIG. 7 shows a configuration of a display unit 2 according to a second embodiment of the present disclosure. In this display unit 2, a side frame 30 having a caterpillar structure in which rigid sections 31 and deformable cushion sections 32 are alternately arranged is provided at at least one side of the panel 10 (for example, at one or both of the long sides 10B). Further, driver ICs 24 are mounted along the respective rigid sections 31. Except for this, the display unit 2 is similar to the first embodiment in configuration, function, and effect. Therefore, elements corresponding to those in the first embodiment are denoted with the same reference numerals in the following description.

The panel 10, the elongated driver ICs 21, and the FPC 13 are configured similarly to the first embodiment.

The side frame 30 defines the bending direction of the panel 10, and has the caterpillar structure in which the rigid sections 31 and the deformable cushion sections 32 are alternately arranged. The rigid sections 31 hold a part of the long side 10B of the panel 10, and may be made of a resin material such as ABS (acrylonitrile butadiene styrene), PET (polyethylene terephthalate), and PC (polycarbonate), for example. The cushion sections 32 are provided between the rigid sections 31 adjacent thereto, and may be deformed following the bending of the panel 10. In other words, the cushion section 32 allows the bending and deforming of the panel 10, and also has a function as a buffer member interposed between the rigid sections 31 which have rigidity and are undeformable (difficult to be deformed). The cushion sections 32 may be made of a cushion material or an embedded resin, or may be configured of a hinge structure, for example.

As described above, the driver ICs 24 are mounted along the respective rigid sections 31. In other words, each driver IC 24 is mounted in a region along one of the rigid sections 31 on the panel 10, and does not extend over that region to reach a region along the cushion section 32. With this configuration, the display unit 2 is capable of increasing the flexibility and the mechanical reliability of the panel 10.

A dimensional ratio of the driver IC 24 (an aspect ratio in one embodiment where the driver IC 24 is rectangular) is not specifically limited unlike the compact driver IC 22 of the first embodiment. This is because the bending direction of the panel 10 is defined by the rigid sections 31 of the side frame 30 in the present embodiment. It should be noted that, as with the compact driver IC 22 of the first embodiment, the driver IC 24 may have the low dimensional ratio that allows the panel 10 to be bent to the minimum bending radius.

In the display unit 2, when the panel 10 is bent, the cushion sections 32 of the side frame 30 are deformed following the bending of the panel 10, but the rigid sections 31 are not deformed. Consequently, a stress exerted on the driver IC 24 mounted along the rigid section 31 is reduced, and a risk of damage due to the bending of the panel 10 is decreased.

As described above, in the present embodiment, the side frame 30 in which the rigid sections 31 and the deformable cushion sections 32 are alternately arranged is provided at at least one side of the panel 10, and the driver ICs 24 are mounted along the respective rigid sections 31. Thus, a stress exerted on the driver ICs 24 when the panel 10 is bent is reduced. Hence, it is possible to increase the flexibility and the mechanical reliability of the panel 10 even when the dimensional ratio (the aspect ratio in one embodiment where the driver IC 24 is rectangular) of the driver IC 24 is high.

### Application Example

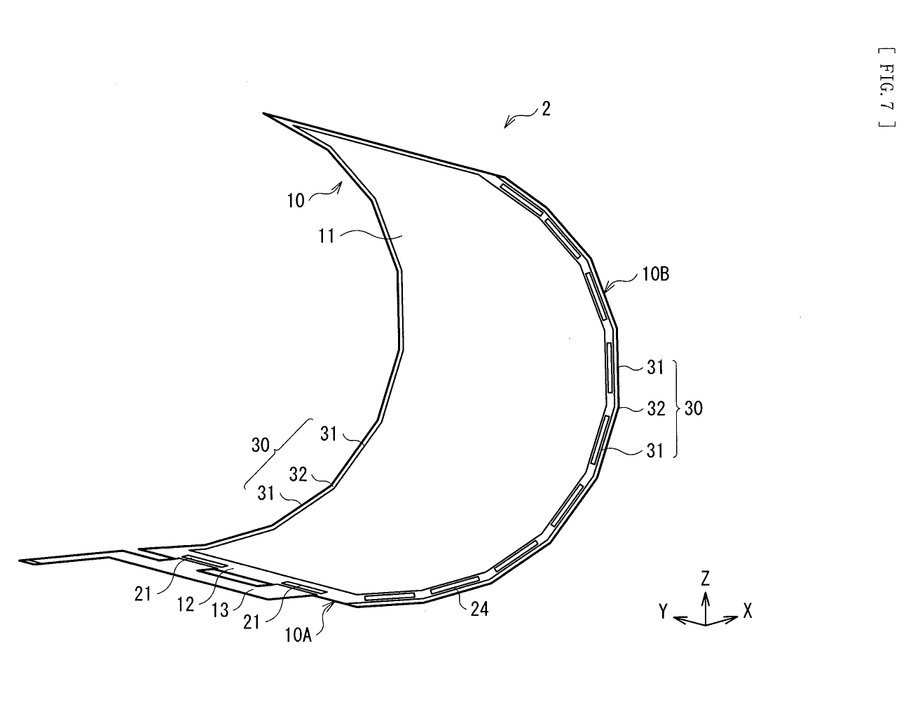

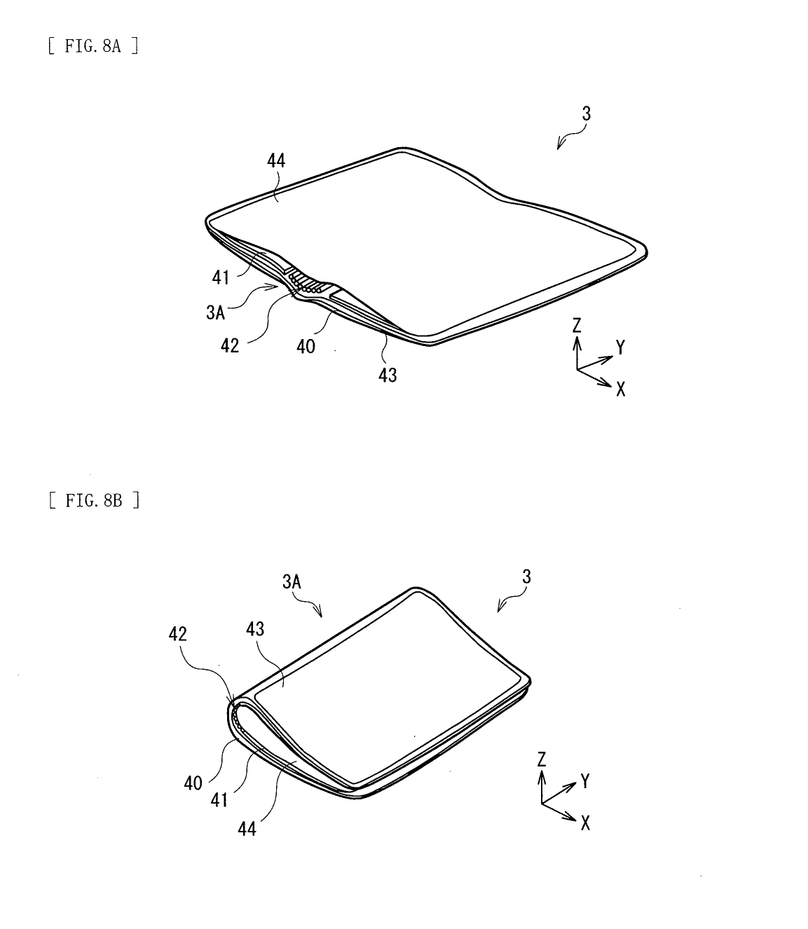

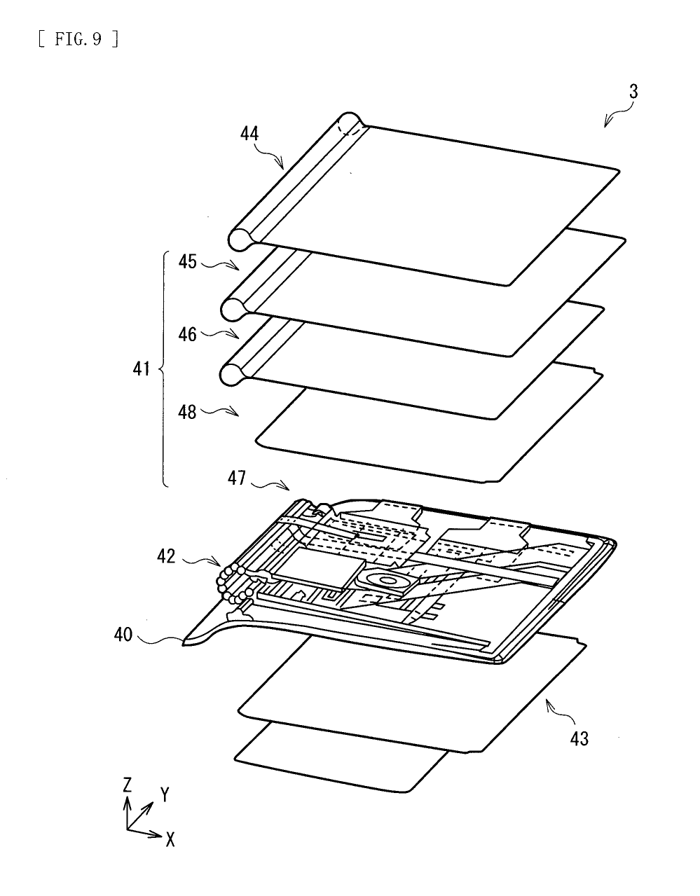

FIGS. 8A and 8B are perspective views each schematically showing a configuration of an electronic apparatus (electronic book 3) according to an application example of one embodiment of the present disclosure. FIG. 9 shows a part of one side of the electronic book 3 in an exploded manner.

The electronic book 3 is a thin and flexible display formed with use of a flexible material as a component. In the electronic book 3, the unit as a whole may be closed (folded) or opened as is the case with a real book made by putting together a plurality of pieces of paper (pages). A user may browse contents (a page or the like of a book, for example) displayed on the electronic book 3 as if the user is actually reading a book.

The electronic book 3 is provided with, on a supporting substrate 40, a laminated body 41 including a display section 45. The electronic book 3 includes a hinge section 42 at a portion corresponding to “spine” (spine 3A) of a book. A cover 43 is provided on the bottom face side (a side that faces outside in a closed state) of the electronic book 3, and the top face side (a side that faces inside in a closed state) thereof is covered with a protective sheet 44.

The supporting substrate 40 supports the laminated body 41 as a base material of the electronic book 3, and has flexibility.

As illustrated in FIG. 9, for example, the laminated body 41 may have a configuration in which a system board layer 47, a circuit section 48, a detection section 46, and the display section 45 are laminated in order from the supporting substrate 40. Each of these components is configured of a soft material, making it possible to achieve flexibility in a laminated state of such components. It is to be noted that, while an exemplary case where the laminated body 41 is provided on two faces, i.e., a left side face and a right side face, of the electronic book 3 in an opened state is described in the present embodiment, the laminated body 41 may be provided on only one of the left side face and the right side face.

The hinge section 42 is provided at a portion corresponding to the spine 3A of the supporting substrate 40. It is preferable that the hinge section 42 be a curvature-restriction hinge capable of maintaining a predetermined curvature regardless of a bend angle of the supporting substrate 40 (or the electronic book 3), for example.

The cover 43 is an exterior member of the electronic book 3, and is configured of a soft resin film.

The protective sheet 44 protects the display section 45, and forms a display face of the electronic book 3. The protective sheet 44 is so bonded to the supporting substrate 40 as to cover the whole surface thereof, and is configured of a soft resin film having transparency to display light.

The display section 45 is configured of one of the display units 1 and 2 according to the above-described first and second embodiments.

The detection section 46 detects an operation (operation performed mainly along a Z direction) of bending, pressing, or the like by a user. The detection section 46 may include a bending sensor 46B. The bending sensor 46B may be configured of, for example, an acceleration sensor, a force sensor, a pressure sensor, a deformation sensor, a gyro sensor, or the like.

The detection section 46 may also include a location sensor 46A in addition to the bending sensor 46B, and is capable of detecting touch input (input using a stylus, finger(s), hand(s), or the like) by a user. The location sensor 46A detects a position touched by a user as a two-dimensional position coordinate of an X direction and a Y direction. Examples of the location sensor 46A include, for example, a pressure-sensitive sensor, a two-dimensional tracking sensor, a two-dimensional touch sensor, a mesh sensor, and a capacitance-based sensor. The location sensor 46A may be preferably provided in an upper layer of the display section 45, for example. With sensing in three axis directions of X, Y, and Z using the location sensor 46A and the bending sensor 46B, it is possible to detect a location, an extent of bending, and the like of a bending operation by a user. It should be noted that a configuration of the detection section 46 is not limited to a combination of the location sensor 46A and the bending sensor 46B, and any triaxial sensor may be used.

The system board layer 47 may be provided with, for example, a system board on which electronic parts are mounted, a hard disk drive (HDD), a cooling fan, and the like. The system board may be mounted with, for example, electronic parts including CPU (central processing unit), a main memory, a chipset, control circuits for various kinds of driving, and the like. The hard disk drive is connected to a connector terminal of the system board, and includes a hard disk. The hard disk drive reads and writes information in the hard disk. The cooling fan cools the CPU mounted to the system board and other elements that generate heat.

The circuit section 48 is a circuit section that includes a TFT (thin-film transistor) configured to drive each of the display section 45 and the detection section 46. The TFT can be an organic TFT or other suitable TFT, for example.

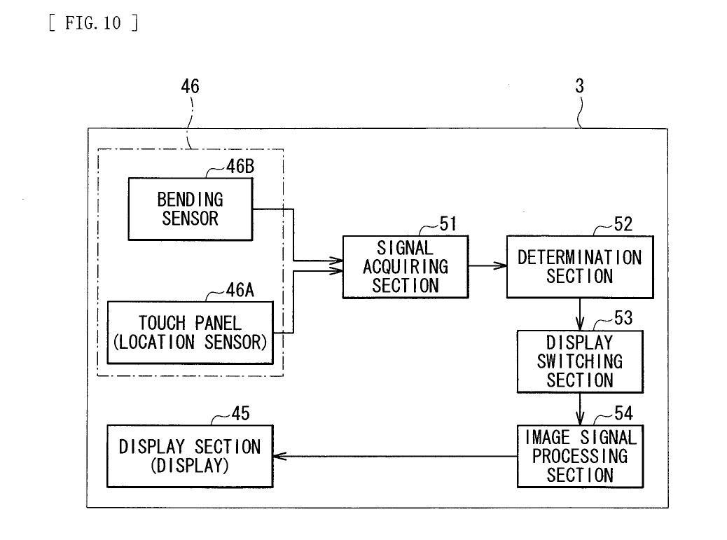

FIG. 10 shows a functional configuration of the electronic book 3. The electronic book 3 includes a signal acquiring section 51, a determination section 52, a display switching section 53, and an image signal processing section 54. The signal acquiring section 51 is connected to the location sensor 46A and the bending sensor 46B provided as components.

The signal acquiring section 51 acquires a signal representing two-dimensional location information detected by the location sensor 46A. The signal acquiring section 51 also acquires a signal representing bend information (in a Z direction) detected by the bending sensor 46B.

The determination section 52 determines whether the electronic book 3 is bent at a local portion on the basis of a result of detection by the sensors.

The display switching section 53 switches display contents of the display section 45 on the basis of a result of detection by the sensors. Specifically, when the determination section 52 determines that a predetermined region of the electronic book 3 is bent, the display switching section 53 causes the display section 45 to display an image representing page turning (page flipping), scrolling, or the like.

The image signal processing section 54 generates an image (image signal) to be displayed on the display section 45. For example, the electronic book 3 displays a desired page of contents downloaded through a network on the display section 45.

It is to be noted that a function of each of the above-described signal acquiring section 51, the determination section 52, the display switching section 53, and the image signal processing section 54 may be achieved by a dedicated control device or an unillustrated processor (CPU) configured to implement a program. A program and data indicative of a procedure to be implemented by a processor may be stored in a hardware resource including storage devices such as RAM (random access memory), ROM (read only memory), and HDD (hard disk drive).

In the electronic book 3, each of the supporting substrate 40, the laminated body 41, the cover 43, and the protective sheet 44 is made of a soft material (has flexibility), and the spine 3A is provided at the predetermined hinge section 42. Thus, a user is allowed to open and close the electronic book 3 in the same manner as handling a real paper book. For example, in a state where the electronic book 3 is opened as illustrated in FIG. 8A, when an image (an image of a page of a book for example) is displayed on the display section 45, a user is allowed to read the page while holding the electronic book 3 with one hand or both hands, or while opening (placing) the electronic book 3 on a stand or the like.

When a user performs a predetermined action that results in a change in a physical form of the electronic book 3 in a state where certain contents are displayed on the display section 45, such action is detected by the detection section 46 and the display switching section 53 switches the display contents. Specifically, in the case where the detection section 46 detects local deflection (such as bending including torsion, pressing, and the like) of the supporting substrate 40 (the electronic book 3), the display switching section 53 switches display contents, and displays contents representing, for example, a page turning action or a scroll action. In other words, an inputting operation (such as a page turning action and a scroll action) by a user is sensed, and contents corresponding to the sensed action is displayed (for example, other page is displayed, other line is displayed, etc.).

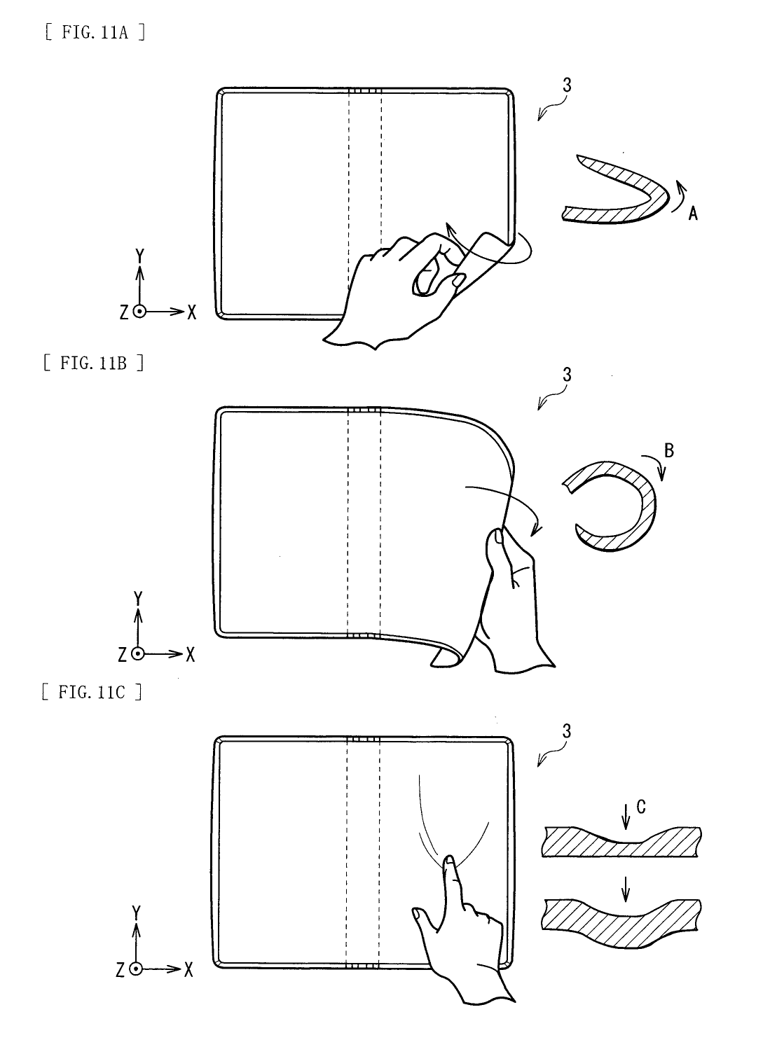

Specifically, the signal acquiring section 51 acquires XY position coordinate information from the location sensor 46A, and acquires, from the bending sensor 46B, displacement in a Z direction as bend (deflection) information, and outputs the acquired information to the determination section 52. The determination section 52 specifies a location (a location in contact with finger(s) or the like) in the XY plane where an inputting action is performed by a user on the basis of the acquired XY position coordinate information, and determines whether the electronic book 3 is bent by the user on the basis of the acquired bend information. It is to be noted that this determination may be made by, for example, comparison with a threshold level of bending amount preliminarily held. For example, when the bending amount corresponding to the acquired bend information is smaller than the threshold level, then the determination section 52 determines as “not being bent”, whereas when the bending amount is equal to or greater than the threshold level, then the determination section 52 determines as “being bent”. In this way, inputting operations by a user as illustrated in FIGS. 11A to 11C are sensed.

That is, it is possible to sense an action A of bending an end region including corner portions and the like of the electronic book 3 to a frontward side as illustrated in FIG. 11A. Likewise, it is also possible to sense an action B of bending and twisting an end portion of the electronic book 3 to a backward side as illustrated in FIG. 11B, and an action C of moving and pressing (pressing) an end portion of the electronic book 3 as illustrated in FIG. 11C. Among them, for example, the actions illustrated in FIGS. 11A and 11B are those generally performed when turning (flipping) a page. On the other hand, the action illustrated in FIG. 11C is one of actions generally performed when a user performs a scroll action. It is to be noted that, since the scroll operation involves movement in the XY plane, it is preferable that whether the XY position coordinate is moved be determined together at the time of determining the bending state. It should be noted that, these actions are merely illustrative and not limitative, and are representative examples of actions that are generally performed when a user turns (flips) a page of a book, or performs a scroll.

Then, if the user inputting operation sensed by the detection section 46 is the page turning actions illustrated in FIGS. 11A and 11B for example, then the display switching section 53 switches the display contents to, for example, the contents representing the previous page or the next page of the page that has been displayed. At this time, such a display may be carried out in which a currently-displayed page is instantly switched to the previous page or the next page on the display section 45, or such a “performance” display may be carried out in which contents of the next page appears in a flipped part as in the case of flipping a page of a real book. On the other hand, if the user inputting operation sensed by the detection section 46 is the scroll action illustrated in FIG. 11C for example, then the display switching section 53 switches the display contents to, for example, contents representing previous line(s) or next line(s) of a predetermined line (or paragraph) of a page that has been displayed.

As described above, a user is allowed to perform an operation such as page turning and scrolling by the action of locally bending the electronic book 3. Specifically, since it is only necessary to operate the electronic book 3 in a similar way to an actual book, a correlation between an inputting operation and resulting display contents to be changed is high, making it easier for a user to relate intuitively the inputting operation and the display contents to be changed.

Hereinabove, while the present disclosure has been described with reference to some example embodiments and application example, the present disclosure is not limited thereto, and various modifications may be made. Also, for example, while the example embodiments and application example are described with specific reference to the configurations of the display units 1 and 2 and the electronic book 3, all of the elements do not have to be included, and other elements may be further included optionally.

In addition, while, in the above-described example embodiments and application example, an exemplary case in which the planar shape of the supporting substrate 40 is rectangular is described, the planar shape of the supporting substrate 40 is not limited thereto. Other shapes such as a square shape or other polygonal shapes, a circular shape, and an elliptical shape may also be adopted.

Further, while, in the above-described application example, an exemplary case in which the region corresponding to the spine 3A of the electronic book 3 is so formed to extend as to bisect the supporting substrate 40 is described, the form of the spine 3A of the electronic book 3 is not limited thereto. For example, the spine 3A of the electronic book 3 may be formed to extend at either a region on the left side or on right side of the supporting substrate 40. That is, such a configuration that one side of the supporting substrate is exposed from the other side in a folded state may also be adopted. In addition, the number of the spine 3A of the electronic book 3 is not limited to one, and may be plural.

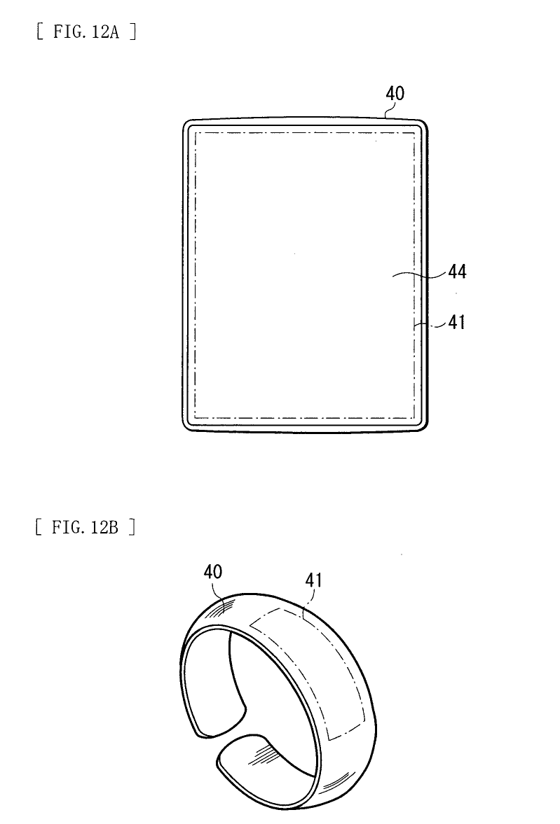

Further, the supporting substrate 40 of the application example does not have to be foldable. As illustrated in FIG. 12A for example, a display unit or an electronic apparatus of so-called tablet-type in which the supporting substrate 40 is formed in a single plate form is also applicable. In addition, as illustrated in FIG. 12B for example, the supporting substrate may also be formed in a band shape attachable to arm or the like. Further, although not shown in the figures, the above-described foldable, or tablet-type display unit or electronic apparatus may also be configured in such a manner that other units such as a keyboard are connectable.

Additionally, in the above-described example embodiments and application example, an electronic book is described as an example of the display unit or the electronic apparatus of according to example embodiments of present disclosure. However, the display unit or the electronic apparatus of example embodiments of the present disclosure may also be employed in other electronic apparatuses. Such electronic apparatuses can be various kinds of mobile units (note-type PCs (personal computers), mobile audio players, mobile phones, PDAs (personal digital assistants), and the like. In addition, the display unit or the electronic apparatus of the example embodiments of the present disclosure may be used not only as a book reader, but also as general display units and general electronic apparatuses with which a music player, a movie player, a picture viewer, a map application, a web browser, or the like may be used and browsed.

Furthermore, the technology encompasses any possible combination of some or all of the various embodiments and modifications described herein and incorporated herein.

It is possible to achieve at least the following configurations from the above-described example embodiments of the disclosure.

(1) A display panel comprising:

a display region in which a plurality of display units are disposed on a flexible substrate, and

a peripheral region in which a plurality of semiconductor devices are disposed, the plurality of semiconductor devices being connected to ones of the display units,

wherein the plurality of semiconductor devices are configured such that the display panel may bend to a minimum bending radius along at least one side thereof.

(2) The display panel as described in (1),

wherein the plurality of semiconductor devices include first semiconductor devices disposed directly on the flexible substrate along a first side of the display region and second semiconductor devices disposed directly on the flexible substrate along a second side of the display region adjacent to the first side.

(3) The display panel as described in (2),

wherein each of the second semiconductor devices has a lower dimensional ratio than any of the first semiconductor devices, where a dimensional ratio is a length of a longest dimension in a plane parallel to the substrate divided by a length of a shortest dimension in a plane parallel to the substrate.

(4) The display panel as described in (2),

wherein each of the second semiconductor devices have a dimensional ratio less than or equal to 2, where a dimensional ratio is a length of a longest dimension in a plane parallel to the substrate divided by a length of a shortest dimension in a plane parallel to the substrate.

(5) The display panel as described in (2),

wherein, for each of the second semiconductor devices, its respective length in the first direction is less than or equal to its respective length in the second direction.

(6) The display panel as described in (2),

wherein each of the second semiconductor devices is approximately square.

(7) The display panel as described in (2), wherein each of the second semiconductor devices is approximately circular.

(8) The display panel as described in (2),

wherein each of the second semiconductor devices is approximately hexagonal.

(9) The display panel as described in (2),

wherein the plurality of semiconductor devices comprise driver integrated circuits configured to drive the plurality of display units.

(10) The display panel as described in (2),

wherein a longest dimension of each of the second semiconductor devices is shorter than a longest dimension of any of the first semiconductor devices.

(11) The display panel as described in (2),

wherein a dimension of each of the second semiconductor devices in the second direction is less than or equal to πR/3, where R is the minimum bending radius along the second direction.

(12) The display panel as described in (1),

wherein the plurality of semiconductor devices include first semiconductor devices disposed along a first side of the display region and second semiconductor devices disposed along a second side of the display region adjacent to the first side,

wherein the display panel includes a side frame disposed on the second side of the display region, the side frame including rigid sections and deformable cushion sections alternately disposed, and

wherein the second semiconductor devices are disposed on regions corresponding to the rigid sections of the side frame.

(13) An electronic apparatus comprising the display panel as described in (1),

(14) The electronic apparatus as described in (13),

further comprising a flexible laminated body that includes:

a display section comprising the display panel, and

a detection section configured to detect an operation of a user.

(15) The electronic apparatus as described in (14),

wherein operations of a user detectable by the detection section include bending of the flexible laminated body and pressing on the flexible laminated body.

(16) The electronic apparatus as described in (15),

wherein the detection section includes a location sensor configured to detect a location of a user input device, said user input device including any one of a stylus and a finger of a user.

(17) The electronic apparatus as described in (15),

wherein the electronic apparatus is configured to change an image displayed by the display section in response to a detected operation of a user.

(18) The electronic apparatus as described in (17),

wherein the electronic apparatus is configured to change an image displayed by the display section in response to detecting a user bending the laminated body.

(19) A display unit, including:

a panel having flexibility; and

a semiconductor device directly mounted to the panel and having a dimensional ratio of a largest outer size to a smallest outer size, the dimensional ratio having a small value that allows the panel to be bent to a minimum bending radius.

(20) The display unit according to (19), wherein a size in a bending direction of the semiconductor device is πR/3 or less, where R is the minimum bending radius of the panel.

(21) The display unit according to (19) or (20), wherein the semiconductor device has a square planar shape.

(22) The display unit according to (19) or (20), wherein the semiconductor device has a regular polygonal planar shape.

(23) A display unit, including:

a panel having flexibility;

semiconductor devices that are directly mounted to the panel; and

a side frame provided at at least one side of the panel,

wherein the side frame includes rigid sections and cushion sections, each of the rigid sections holding a part of the at least one side of the panel, and each of the cushion sections being provided between the adjacent rigid sections and being deformable following bending of the panel, and

wherein the semiconductor devices are mounted along the respective rigid sections.

(24) A display unit, including:

a panel having flexibility; and

a first semiconductor device and a second semiconductor device that are directly mounted to the panel,

wherein the panel includes a first side and a second side, the first side extending in a first direction and the second side extending in a second direction different from the first direction, and

wherein a size in the first direction of the first semiconductor device mounted at the first side is shorter than a size in the second direction of the second semiconductor device mounted at the second side.

(25) The display unit according to (24), wherein the second side of the panel is connected with a flexible printed circuit.

(26) An electronic apparatus with a display unit, the display unit including:

a panel having flexibility; and

a semiconductor device directly mounted to the panel and having a dimensional ratio of a largest outer size to a smallest outer size, the dimensional ratio having a small value that allows the panel to be bent to a minimum bending radius.

(27) An electronic apparatus with a display unit, the display unit including:

a panel having flexibility;

semiconductor devices that are directly mounted to the panel; and

a side frame provided at at least one side of the panel,

wherein the side frame includes rigid sections and cushion sections, each of the rigid sections holding a part of the at least one side of the panel, and each of the cushion sections being provided between the adjacent rigid sections and being deformable following bending of the panel, and

wherein the semiconductor devices are mounted along the respective rigid sections.

(28) An electronic apparatus with a display unit, the display unit including:

a panel having flexibility; and

a first semiconductor device and a second semiconductor device that are directly mounted to the panel,

wherein the panel includes a first side and a second side, the first side extending in a first direction and the second side extending in a second direction different from the first direction, and

wherein a size in the first direction of the first semiconductor device mounted at the first side is shorter than a size in the second direction of the second semiconductor device mounted at the second side.

The present disclosure contains subject matter related to that disclosed in Japanese Priority Patent Application JP 2012-127983 filed in the Japan Patent Office on Jun. 5, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

1. A display panel comprising:
a display region in which a plurality of display units are disposed on a flexible substrate, and
a peripheral region in which a plurality of semiconductor devices are disposed, the plurality of semiconductor devices being connected to ones of the display units,
wherein the plurality of semiconductor devices are configured such that the display panel may bend to a minimum bending radius along at least one side thereof.

2. The display panel of claim 1,
wherein the plurality of semiconductor devices include first semiconductor devices disposed directly on the flexible substrate along a first side of the display region and second semiconductor devices disposed directly on the flexible substrate along a second side of the display region adjacent to the first side.

3. The display panel of claim 2,
wherein each of the second semiconductor devices has a lower dimensional ratio than any of the first semiconductor devices, where a dimensional ratio is a length of a longest dimension in a plane parallel to the substrate divided by a length of a shortest dimension in a plane parallel to the substrate.

4. The display panel of claim 2,
wherein each of the second semiconductor devices have a dimensional ratio less than or equal to 2, where a dimensional ratio is a length of a longest dimension in a plane parallel to the substrate divided by a length of a shortest dimension in a plane parallel to the substrate.

5. The display panel of claim 2,
wherein, for each of the second semiconductor devices, its respective length in the first direction is less than or equal to its respective length in the second direction.

6. The display panel of claim 2,
wherein each of the second semiconductor devices is approximately square.

7. The display panel of claim 2,
wherein each of the second semiconductor devices is approximately circular.

8. The display panel of claim 2,
wherein each of the second semiconductor devices is approximately hexagonal.

9. The display panel of claim 2,
wherein the plurality of semiconductor devices comprise driver integrated circuits configured to drive the plurality of display units.

10. The display panel of claim 2,
wherein a longest dimension of each of the second semiconductor devices is shorter than a longest dimension of any of the first semiconductor devices.

11. The display panel of claim 2,
wherein a dimension of each of the second semiconductor devices in the second direction is less than or equal to πR/3, where R is the minimum bending radius along the second direction.

12. The display panel of claim 1,
wherein the plurality of semiconductor devices include first semiconductor devices disposed along a first side of the display region and second semiconductor devices disposed along a second side of the display region adjacent to the first side,
wherein the display panel includes a side frame disposed on the second side of the display region, the side frame including rigid sections and deformable cushion sections alternately disposed, and
wherein the second semiconductor devices are disposed on regions corresponding to the rigid sections of the side frame.

13. An electronic apparatus comprising the display panel of claim 1,

14. The electronic apparatus of claim 13,
further comprising a flexible laminated body that includes:
a display section comprising the display panel, and
a detection section configured to detect an operation of a user.

15. The electronic apparatus of claim 14,
wherein operations of a user detectable by the detection section include bending of the flexible laminated body and pressing on the flexible laminated body.

16. The electronic apparatus of claim 15,
wherein the detection section includes a location sensor configured to detect a location of a user input device, said user input device including any one of a stylus and a finger of a user.

17. The electronic apparatus of claim 15,
wherein the electronic apparatus is configured to change an image displayed by the display section in response to a detected operation of a user.

18. The electronic apparatus of claim 17,
wherein the electronic apparatus is configured to change an image displayed by the display section in response to detecting a user bending the laminated body.
